(19) United States
(12) Patent Application Publication
(10) Pub. No.: US 2026/0179877 A1
(43) Pub. Date: Jun. 25, 2026

(54) SUBSTRATE PROCESSING METHOD AND SUBSTRATE PROCESSING APPARATUS

(71) Applicant: Tokyo Electron Limited, Tokyo (JP)

(72) Inventors: Shinichi TANABE, Tokyo (JP); Hitoshi MIURA, Tokyo (JP); Atsuki FUKAZAWA, Tokyo (JP); Hiroki MAEHARA, Tokyo (JP); Kazuya DOBASHI, Yamanashi (JP)

(21) Appl. No.: 19/541,974

(22) Filed: Feb. 17, 2026

Related U.S. Application Data
(63) Continuation of application No. PCT/JP2024/030078, filed on Aug. 23, 2024.

(30) Foreign Application Priority Data
Aug. 31, 2023 (JP) 2023-141486

(51) Int. Cl. H01J 37/305; H01J 37/18

(52) U.S. Cl. CPC H01J 37/3053; H01J 37/18

(57) ABSTRACT

A substrate processing method includes etching a film of a sheet-like material by irradiating a substrate on which the film of the sheet-like material is formed with particles.

### CROSS-REFERENCE TO RELATED APPLICATIONS

This application is a continuation application of International Application No. PCT/JP2024/030078 filed on Aug. 23, 2024, and designating the U.S., which is based upon and claims priority to Japanese Patent Application No. 2023-141486 filed on Aug. 31, 2023, the entire contents of which are incorporated herein by reference.

### BACKGROUND

### 1. Technical Field

The present disclosure relates to a substrate processing method and a substrate processing apparatus.

### 2. Description of Related Art

Various two-dimensional materials have attracted attention as semiconductor materials capable of replacing silicone. Transition metal dichalcogenides such as molybdenum disulfide (MoS₂) and graphene are known as two-dimensional materials. Due to the specific two-dimensional structure of two-dimensional materials, they have distinctive electrical characteristics such as high electron mobility. Therefore, transition metal dichalcogenides and stacked films of transition metal dichalcogenides are expected to be used not only as materials for forming channel layers of transistors, transparent conductive films, and wirings, but also as key materials for electronic devices such as high-frequency devices and sensors. Japanese Unexamined Patent Application Publication No. 2022-101619 (hereinafter “Patent Document 1”) discloses a method for forming a film of transition metal dichalcogenides, which are one type of two-dimensional materials, by an atomic layer deposition (ALD) process.

### SUMMARY

According to one aspect, the present disclosure provides a substrate processing method including etching a film of a sheet-like material by irradiating a substrate on which the film of the sheet-like material is formed with particles.

### BRIEF DESCRIPTION OF THE DRAWINGS

FIG. 1 is an example of a configuration diagram of a substrate processing apparatus according to an embodiment;

FIG. 2 is an example of a configuration diagram of an etching apparatus according to the embodiment;

FIG. 3 is a flowchart illustrating an example of a substrate processing method according to the embodiment;

FIG. 4A is an example of a schematic cross-sectional view of a substrate W in a step of a substrate processing method according to the embodiment;

FIG. 4B is an example of a schematic cross-sectional view of the substrate W in another step of the substrate processing method according to the embodiment;

FIG. 4C is an example of a schematic cross-sectional view of the substrate W in yet another step of the substrate processing method according to the embodiment;

FIG. 5 is an example of a schematic diagram illustrating binding energy in a film of a sheet-like material;

FIG. 6A is an example of a schematic cross-sectional view of a substrate illustrating an incident direction of particles; and

FIG. 6B is an example of a schematic cross-sectional view of the substrate illustrating another incident direction of particles.

### DETAILED DESCRIPTION

According to one aspect, the present disclosure can provide a substrate processing method and a film forming apparatus for selectively etching a film of a sheet-like material.

Hereinafter, an embodiment of the present disclosure will be described with reference to the drawings. In each of the drawings, the same components are denoted by the same reference numerals and redundant descriptions may be omitted.

### (Processing System)

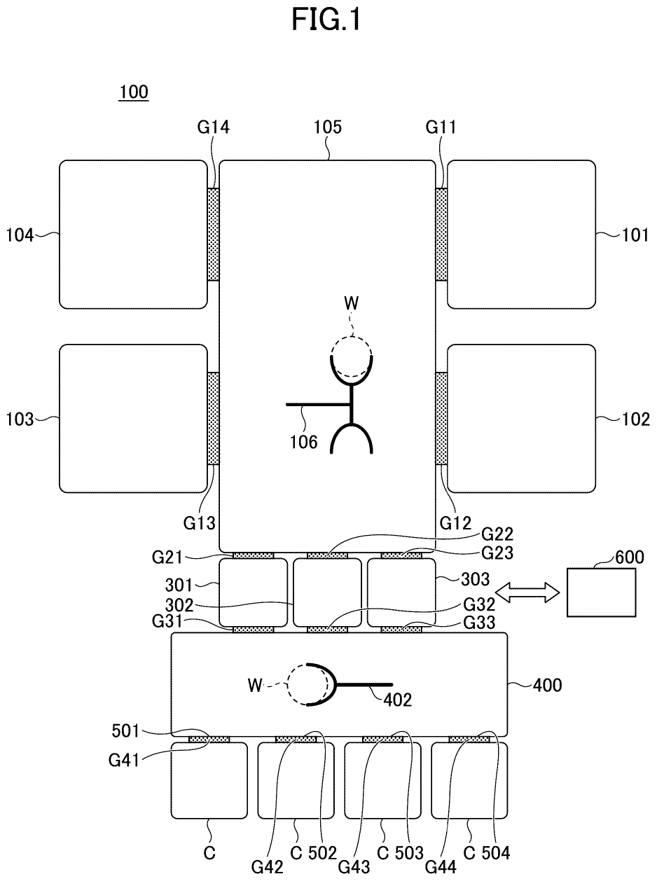

A substrate processing apparatus 100 used in a substrate processing method according to an embodiment will be described with reference to FIG. 1. FIG. 1 is an example of a configuration diagram of the substrate processing apparatus 100 according the embodiment.

The substrate processing apparatus 100 includes processing chambers 101 through 104, a vacuum transfer chamber 105, load lock chambers 301 through 303, an atmospheric transfer chamber 400, load ports 501 through 504, and a control device 600.

The processing chambers 101 through 104 are connected to the vacuum transfer chamber 105 via gate valves G11 through G14, respectively. The inside of the processing chambers 101 through 104 is depressurized to a predetermined vacuum atmosphere, and a desired processing is performed on a substrate W inside the processing chambers 101 through 104.

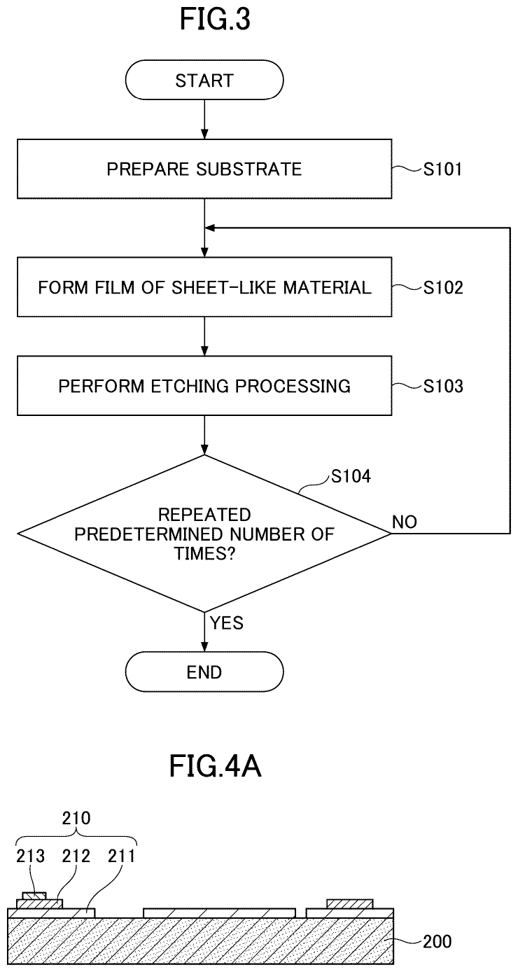

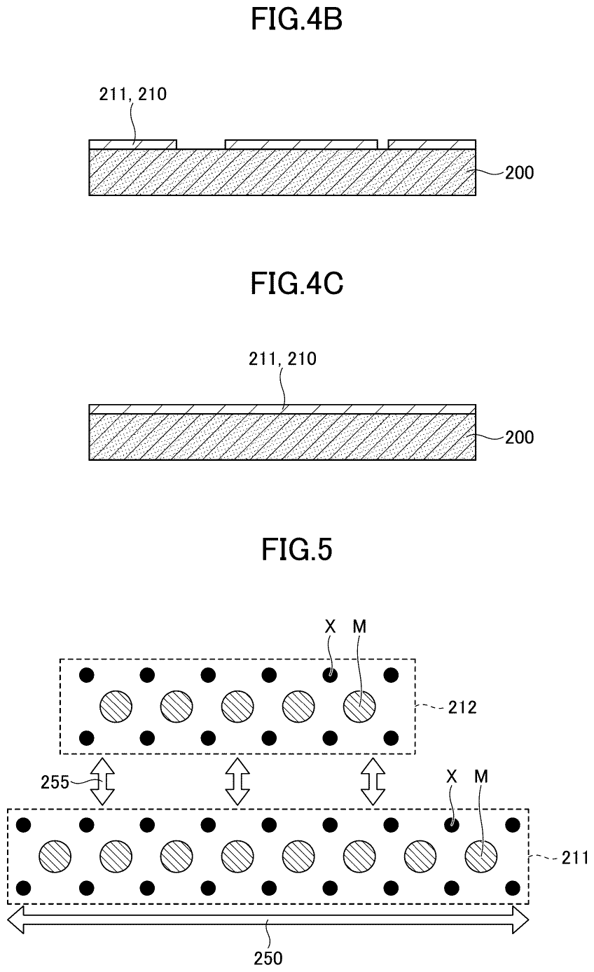

The processing chamber 101 is a film-forming apparatus for forming a film 210 of a sheet-like material (see FIG. 4A, which will be described later) on a substrate W by performing step S102 of FIG. 3, which will be described later.

Herein, the sheet-like material is a two-dimensional material (2D material) in which atoms are bonded in a sheet shape. Examples of the sheet-like material include chalcogenide and graphene, for example. Chalcogenide is a material in which a metal element M and a chalcogen element X are bonded. Examples of the metal element M include, for example, molybdenum (Mo), tungsten (W), bismuth (Bi), antimony (Sb), tin (Sn), germanium (Ge), and the like, but the metal element M is not limited thereto. Examples of the chalcogen element X include, for example, sulfur (S), selenium (Se), tellurium (Te), and the like, but the chalcogen element X is not limited thereto.

The processing chamber 101 may be, for example, an ALD (atomic layer deposition) apparatus. The processing chamber 101, which is an ALD apparatus, has a substrate support (not illustrated) configured to support a substrate W, a processing vessel (not illustrated) for accommodating the substrate support, and a gas supply (not illustrated) for supplying a process gas (raw material gas, reaction gas, etc.) into the processing vessel. The processing vessel has a predetermined vacuum atmosphere. The processing chamber 101 forms a film 210 of a sheet-like material on a substrate W by alternately supplying a raw material gas and a reaction gas from the gas supply into the processing vessel. The processing chamber 101 may perform pretreatment or post-treatment on a substrate by supplying a process gas into the processing vessel. The processing chamber 101 may be a thermal ALD apparatus or a plasma ALD apparatus.

The processing chamber 101 may be a CVD (chemical vapor deposition) apparatus, for example. The processing chamber 101 as a CVD apparatus has a substrate support (not illustrated) configured to support a substrate W, a processing vessel (not illustrated) for accommodating the substrate support portion, and a gas supply (not illustrated) for supplying a process gas (raw material gas, reaction gas, etc.) into the processing vessel. The processing vessel has a predetermined vacuum atmosphere. The processing chamber 101 simultaneously supplies a raw material gas and a reaction gas from the gas supply into the processing vessel, thereby forming a film 210 of a sheet-like material on a substrate W. The processing chamber 101 may perform pretreatment or post-treatment on a substrate by supplying a process gas into the processing vessel. The processing chamber 101 may be a thermal CVD apparatus or a plasma CVD apparatus.

The processing chamber 101 may be a PVD (physical vapor deposition) device, for example. The processing chamber 101 as the PVD apparatus has a substrate support (not illustrated) configured to support a substrate W, a processing vessel (not illustrated) for accommodating the substrate support, and a target (not illustrated) provided in the processing vessel and containing a sheet-like material. The processing vessel has a predetermined vacuum atmosphere. The processing chamber 101 discharges sputtered particles from the target containing the sheet-like material to form a sheet-like material film 210 on a substrate W. The PVD apparatus may be an apparatus configured to perform film formation processing by selectively using a plurality of sources in a multi-cathode system, the sources including RF sputtering, DC sputtering, ion beam sputtering, and the like.

Although the processing chamber 101 has been described as an ALD apparatus, a CVD apparatus, or a PVD apparatus, it is not limited thereto, and may be a film forming apparatus for forming a film 210 of a sheet-like material on a substrate W by other methods.

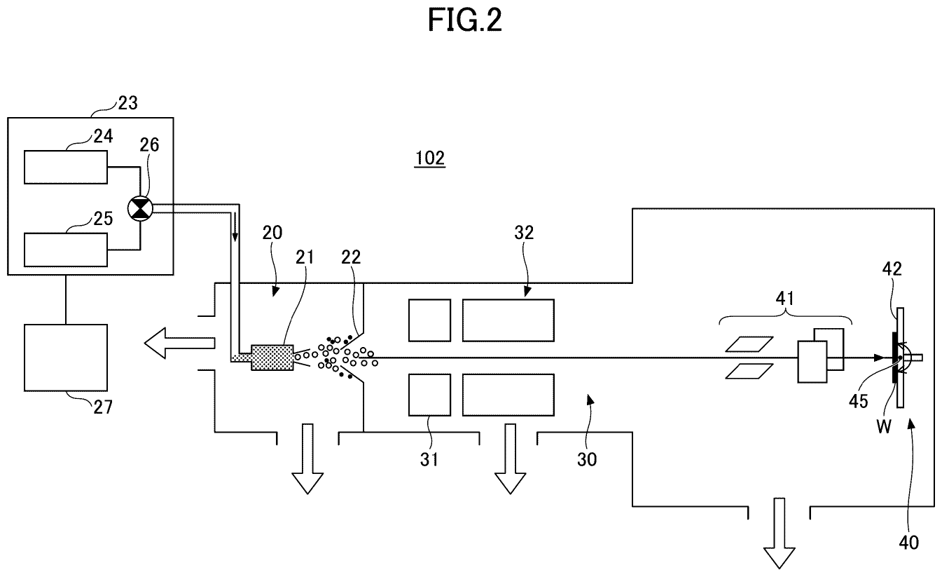

The processing chamber 102 is an etching apparatus for selectively etching a film 210 of a sheet-like material by performing step S103 of FIG. 2, which will be described later. The configuration of the processing chamber 102 will be described later with reference to FIG. 2.

The processing chambers 103 and 104 may perform the same treatment process as any of the processing chambers 101 and 102, or may perform a treatment process different from that of the processing chambers 101 and 102, such as annealing, substrate pretreatment (e.g., UV ozone treatment), or film formation for an electrode or a gate insulating film.

The vacuum transfer chamber 105 is depressurized to a predetermined vacuum atmosphere. The vacuum transfer chamber 105 is an example of a transfer apparatus for transferring a substrate W. The vacuum transfer chamber 105 is provided with a transfer mechanism 106 configured to transfer a substrate W in a depressurized state. The transfer mechanism 106 transfers a substrate W to the processing chambers 101 through 104 and the load lock chambers 301 through 303.

The load lock chambers 301 through 303 are connected to the vacuum transfer chamber 105 via gate valves G21 through G23, and are connected to the atmospheric transfer chamber 400 via gate valves G31 through G33. The load lock chambers 301 through 303 can be switched between an atmospheric atmosphere and a vacuum atmosphere.

The atmospheric transfer chamber 400 is an atmospheric atmosphere, and a downflow of clean air is formed, for example. An aligner (not illustrated) for aligning a substrate W is provided in the atmospheric transfer chamber 400. The atmospheric transfer chamber 400 is provided with a transfer mechanism 402. The transfer mechanism 402 transfers a substrate W to the load lock chambers 301 through 303, carriers C of the load ports 501 through 504 described later, and an aligner.

The load ports 501 through 504 are provided on a wall surface of the atmospheric transfer chamber 400. A carrier C in which a substrate W is accommodated, or an empty carrier C, is attached to each of the load ports 501 through 504 via corresponding gate valves G41 through G44. For example, a FOUP (front opening unified pod) can be used as the carrier C.

The control device 600 controls each part of the substrate processing apparatus 100. For example, the control device 600 executes the operation of the processing chambers 101 through 104, the operation of the transfer mechanisms 106 and 402, the opening and closing of the gate valves G11 through G14, the gate valves G21 through G23, the gate valves G31 through G33, and the gate valves G41 through G44, and the switching of the atmosphere in the load lock chambers 301 through 303.

Next, the processing chamber 102 as an etching apparatus for selectively etching the film 210 of the sheet-like material will be described with reference to FIG. 2. FIG. 2 is an example of the configuration of the etching apparatus (processing chamber 102) according to the embodiment. The etching apparatus (processing chamber 102) illustrated in FIG. 2 is a gas cluster ion beam irradiation apparatus, which can irradiate the surface of a substrate W with a gas cluster ion beam (GCIB).

The processing chamber 102 as a gas cluster ion beam irradiation apparatus has a nozzle chamber 20, a source chamber 30, and a main chamber 40. The nozzle chamber 20, the source chamber 30, and the main chamber 40 are exhausted (indicated by hollow arrows in FIG. 2) by an exhaust device (not illustrated), and the inside of the nozzle chamber 20, the source chamber 30, and the main chamber 40 is in a predetermined vacuum atmosphere.

The nozzle chamber 20 has a nozzle 21 for generating a gas cluster and a skimmer 22 for selecting the generated gas cluster.

The nozzle 21 is connected to a gas supplier 23, and a source gas for generating a gas cluster is supplied to the nozzle 21 from the gas supplier 23. The gas supplier 23 is provided with a plurality of gas supply sources so as to supply different types of source gas. Specifically, as illustrated in FIG. 2, a first gas supply source 24, such as a gas cylinder containing a source gas, and a second gas supply source 25 are provided, and a predetermined amount of gas from the first gas supply source 24 and/or the second gas supply source 25 is supplied to the nozzle 21 by a valve 26 provided in the gas supplier 23. Examples of the source gas include, but are not limited to, any gas or mixed gas of N₂, Ar, H₂, He, O₂, CO₂, NF₃, SF₆, CF₄, and CHF₃. A controller 27 is connected to the gas supplier 23, and the source gas is supplied from the first gas supply source 24 or the second gas supply source 25 under the control of the controller 27.

In the gas cluster ion beam irradiation apparatus according to the embodiment, the source gas pressurized to several atmospheres is supplied to the nozzle 21. When the source gas is jetted at supersonic speed from the nozzle 21 into the nozzle chamber 20 that is in a vacuum state, the source gas is rapidly cooled by adiabatic expansion, and a gas cluster is formed by very weak interatomic or intermolecular bonding.

The gas cluster generated in the nozzle 21 is sorted by the skimmer 22 and introduced into the source chamber 30.

The source chamber 30 has an ionizer 31 for ionizing a gas cluster and an accelerator 32 for accelerating an ionized gas cluster. The gas cluster introduced from the skimmer 22 into the source chamber 30 is ionized in the ionizer 31. The gas cluster ionized in the ionizer 31 is accelerated in the accelerator 32.

The main chamber 40 has an electrode part 41 for selecting gas clusters, a support 42 for supporting a substrate W, and an angle adjustor 45 for adjusting the angle of the support 42.

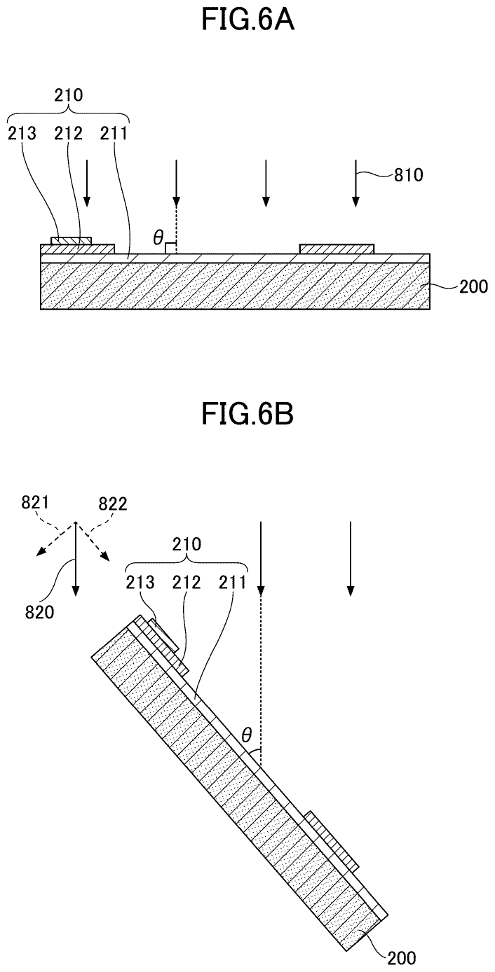

The ionized gas clusters accelerated by the accelerator 32 are selected into gas clusters of a predetermined size or the like by the electrode part 41 provided in the main chamber 40, and radiated onto a substrate W supported by the support 42. The angle adjustor 45 adjusts the angle of the support 42 to adjust an incident angle θ of the gas cluster ion beam incident on a substrate W. Herein, the incident angle θ (see FIGS. 6A and 6B, which will be described later) is the incident angle of the gas cluster ion beam with respect to the surface of a substrate W, and is set to 90° when the incident angle is perpendicular to the surface of the substrate W. The incident angle of the gas cluster ion beam may be perpendicular (θ=90°) or inclined (0°≤θ<90°).

Although the etching apparatus (processing chamber 102) has been described as a gas cluster ion beam irradiation apparatus for irradiating the surface of a substrate W with a gas cluster ion beam (GCIB), the present invention is not limited thereto. The etching apparatus (processing chamber 102) may be a gas cluster beam irradiation apparatus for irradiating the surface of a substrate W with a gas cluster beam (GCB). The etching apparatus (processing chamber 102) may be an ion beam irradiation apparatus for irradiating the surface of a substrate W with an ion beam (IB).

### (Substrate Processing Method)

Next, an example of a substrate processing method using the substrate processing apparatus 100 illustrated in FIG. 1 will be described with reference to FIGS. 3 and 4A through 4C. FIG. 3 is a flowchart illustrating an example of the substrate processing method according to the embodiment. FIGS. 4A through 4C are schematic cross-sectional views of a substrate W in each step of the substrate processing method according to the embodiment.

In step S101, a substrate W is prepared.

In the present example, the prepared substrate W has a base film 200 (see FIG. 4A). Herein, one of the carriers C in which the substrate W having the base film 200 is accommodated is attached to one of the load ports 501 through 504. The control device 600 controls the transfer mechanism 402 or the like to transfer the substrate W from the carrier C to one of the load lock chambers 301 through 303. The control device 600 controls the transfer mechanism 106 or the like to transfer the substrate W from the one of the load lock chambers 301 through 303 to the processing chamber 101.

In step S102, a film 210 of a sheet-like material is formed on the substrate W. The control device 600 controls the processing chamber 101 to form the film 210 of the sheet-like material on the substrate W.

Although it is desirable for the sheet-like material to be a continuous film having a single layer of atoms bonded in a sheet shape or in which the number of layers is uniform across the film, the film 210 of the sheet-like material actually formed in step S102 is not in a desirable state. FIG. 4A schematically illustrates a cross section of the substrate W after the film forming process in step S102. The film 210 of the sheet-like material is formed on the base film 200 of the substrate W. The film 210 of the sheet-like material has a first layer 211 formed directly on the base film 200, a second layer 212 formed on the first layer 211, and a third layer 213 formed on the second layer 212. Although the film 210 of the sheet-like material has been described on the assumption that the first layer 211 through the third layer 213 are formed, the number of layers in the film 210 of the sheet-like material is not limited to this, and the number of layers may be less or more than three.

As illustrated in FIG. 4A, the substrate W has a part where the film 210 of the sheet-like material is not formed on the base film 200, a part where only the first layer 211 is formed on the base film 200, a part where the first layer 211 and the second layer 212 are formed on the base film 200, and a part where the first layer 211 through the third layer 213 are formed on the base film 200. In other words, the film 210 of the sheet-like material on the base film 200 is a discontinuous film, and the number of layers (film thickness) of the film of the sheet-like material differs from part to part.

Upon completion of the film formation processing in the processing chamber 101, the control device 600 controls the transfer mechanism 106 and the like to transfer the substrate W from the processing chamber 101 to the processing chamber 102.

In step S103, the substrate W is subjected to etching processing.

Herein, the binding energy in the film 210 of the sheet-like material will be described with reference to FIG. 5. FIG. 5 is an example of a schematic diagram illustrating the binding energy in the film 210 of the sheet-like material.

The first layer 211 of the film 210 of the sheet-like material is formed by bonding a metal element M and a chalcogen element X in a sheet shape. Similarly, the second layer 212 of the film 210 of the sheet-like material is also formed by bonding the metal element M and the chalcogen element X in a sheet shape. The first layer 211 and the second layer 212 of the film 210 of the sheet-like material are bonded in the in-plane direction by bonds 250 having strong binding energy, such as ionic bonds and covalent bonds. On the other hand, the film 210 of the sheet-like material is bonded in the stacking direction between the first layer 211 and the second layer 212 by bonds 255 having weak binding energy, such as van der Waals forces. For example, when the sheet-like material is MoS₂, a level of the in-plane binding energy (bonds 250 having strong binding energy) is within a range of, for example, 4 [eV/atom] to 6 [eV/atom]. On the other hand, a level of the interlayer binding energy (bonds 255 having weak binding energy) is within a range of, for example, 0.047 [eV/atom] to 0.060 [eV/atom].

In the processing chamber 102, the substrate W is irradiated with particles to peel the second layer 212 (and the third layer 213 and thereafter) from the first layer 211. For example, the processing chamber 102 is a gas cluster ion beam irradiation apparatus illustrated in FIG. 3, in which the substrate W is irradiated with a gas cluster ion beam (GCIB) as particles to be radiated onto the substrate W. The particles to be radiated onto the substrate W are not limited thereto, and a gas cluster beam (GCB) or an ion beam (IB) may be radiated onto the substrate W.

The level of the energy of the particles to be radiated onto the substrate W is preferably higher than the level of the binding energy between the layers and lower than the level of the binding energy in the plane. Specifically, the level of the energy of the particles to be radiated onto the substrate W is preferably equal to or greater than 0.05 [eV/atom] and equal to or less than 1 [eV/atom] when the particles are single atoms, and preferably is equal to or greater than 0.05 [eV/molecule] and equal to or less than 1 [eV/molecule] when the particles are molecules.

Thus, the particles having a higher energy level than the binding energy between the layers of the first layer 211 and the second layer 212 are radiated, the second layer 212 (and the third layer 213 and thereafter) is peeled from the first layer 211, while the breaking of the bonds in the plane of the first layer 211 by the radiated particles is suppressed.

The area of the first layer 211 is larger than that of the second layer 212. Therefore, the interlayer bonding between the base film 200 and the first layer 211 is stronger than that between the first layer 211 and the second layer 212. Therefore, the second layer 212 (and the third layer 213 and thereafter) is peeled from the first layer 211 before the first layer 211 starts to peel from the base film 200.

FIGS. 6A and 6B are schematic cross-sectional views of the substrate W illustrating the incident direction of the particles.

As illustrated in FIG. 6A, the incident direction of the particles 810 radiated onto the substrate W may be a direction perpendicular to the irradiated surface (upper surface) of the substrate W (incident angle θ=90°).

As illustrated in FIG. 6B, the incident direction of the particles 820 to be radiated onto the substrate W may be inclined with respect to the irradiated surface (upper surface) of the substrate W (0°≤θ<90°). In this case, the incident direction of the particles 820 has a stacking direction component 821 and an in-plane direction component 822 with respect to the substrate W. By having the in-plane direction component 822 in the incident direction of the particles 820 to be radiated onto the substrate W, the second layer 212 (and the third layer 213 and thereafter) can be suitably peeled from the first layer 211. In the view illustrated in FIG. 6B, the sheet-like material is formed parallel to the upper surface of the substrate W, but this is not limited thereto. The layer of the sheet-like material used in a transistor having a three-dimensional structure or the like is not necessarily formed parallel to the upper surface of the substrate W. Even in this case, the incident direction of the particles 820 to be radiated may be controlled so that the incident direction is inclined (0°≤θ<190°) with respect to the main surface (the surface in the stacking direction) of the sheet-like material.

FIG. 4B schematically illustrates a cross section of the substrate W after the etching processing in step S103. As illustrated in FIG. 4B, the second layer 212 (and the third layer 213 and thereafter) is peeled, thereby forming the sheet-like film 210 formed on the base film 200 as a single layer of the first layer 211.

In other words, in the etching processing of step S103, the second layer 212 and the third layer 213 are selectively etched off of the film 210 of the sheet-like material including the first layer 211, the second layer 212, and the third layer 213. Thus, the film 210 of the sheet-like material formed on the base film 200 can be made a single layer of the first layer 211.

In step S104, it is determined whether one cycle consisting of the film formation processing (step S102) and the etching processing (step S103) has been repeated a predetermined number of times. As illustrated in FIG. 4B, the film 210 of the sheet-like material after the first-time etching processing (step S103) is a discontinuous film, but the discontinuous portion can be compensated by the film formation processing (step S102) performed a second time and thereafter. In addition, an unnecessary layer formed by the film formation processing (step S102) performed a second time and thereafter can be peeled through the etching processing (step S103) performed a second time and thereafter.

If the cycle has not been repeated the predetermined number of times (No in step S104), the control device 600 controls the transfer mechanism 106 and the like to transfer the substrate W from the processing chamber 102 to the processing chamber 101, and controls the processing chamber 101 to perform the film formation processing (step S102) on the substrate W. Next, the control device 600 controls the transfer mechanism 106 and the like to transfer the substrate W from the processing chamber 101 to the processing chamber 102, and controls the processing chamber 102 to perform the etching processing (step S103) on the substrate W. Hereinafter, this cycle is repeated until the number of times of repeating reaches the predetermined number.

When the cycle is repeated the predetermined number of times (Yes in step S104), the processing illustrated in FIG. 3 is completed. For example, the control device 600 controls the transfer mechanism 106 and the like to transfer the substrate W from the processing chamber 102 to one of the load lock chambers 301 through 303. The control device 600 controls the transfer mechanism 402 and the like such that the substrate W received from one of the load lock chambers 301 through 303 is accommodated in one of the carriers C.

FIG. 4C is a diagram schematically illustrating a cross section of the substrate W after repeating the cycle of the film forming processing (step S102) and the etching processing (step S103). As illustrated in FIG. 4C, the first layer 211 can be formed on the base film 200 as a continuous film. The second layer 212 (and the third layer 213 and thereafter) is peeled thereby forming the film 210 of the sheet-like material formed on the base film 200 as a single layer of the first layer 211. Although the film 210 of the sheet-like material illustrated in FIG. 4C is a single layer for the sake of simple description, the film 210 may be a stack of layers of the sheet-like material.

As described above, according to the substrate processing method according to one embodiment, the film 210 of the sheet-like material can be formed as a single layer (the first layer 211) on the base film 200. In addition, the single-layer film 210 of the sheet-like material (the first layer 211) formed on the base film 200 can be a continuous film.

Although the substrate processing method and the substrate processing apparatus have been described above, the present disclosure is not limited to the above-described embodiments, and various modifications and improvements are possible within the scope of the disclosure described in the appended claims.

What is claimed is:

1. A substrate processing method, comprising:
etching a film of a sheet-like material by irradiating a substrate on which the film of the sheet-like material is formed with particles.

2. The substrate processing method according to claim 1, wherein
in the etching the film of the sheet-like material, the particles are incident at an inclination with respect to a main surface of the sheet-like material.

3. The substrate processing method according to claim 1, wherein
an energy level of the particles radiated onto the substrate is higher than an energy level of binding energy between layers of the film of the sheet-like material and lower than an energy level of binding energy in a plane of the film of the sheet-like material.

4. The substrate processing method according to claim 1, wherein
the energy level of the particles radiated onto the substrate is equal to or less than 1 [eV/atom] when the particles are single atoms, and equal to or less than 1 [eV/molecule] when the particles are molecules.

5. The substrate processing method according to claim 1, wherein
the etching the film of the sheet-like material includes irradiating the substrate with one of a gas cluster ion beam, a gas cluster beam, or an ion beam.

6. The substrate processing method according to claim 1, wherein
the sheet-like material is chalcogenide or graphene.

7. The substrate processing method according to claim 1, wherein
chalcogenide as the sheet-like material includes a metal element and a chalcogen element,
the metal element includes any one of molybdenum, tungsten, bismuth, antimony, tin, or germanium, and
the chalcogen element includes any one of sulfur, selenium, or tellurium.

8. The substrate processing method according to claim 1, further comprising:
forming the film of the sheet-like material on the substrate before the etching the film of the sheet-like material, wherein
the forming the film of the sheet-like material on the substrate and the etching the film of the sheet-like material constitute one cycle, and
the one cycle is repeated.

9. A substrate processing apparatus, comprising:
a film forming device configured to form a film of a sheet-like material on a substrate;
an etching device configured to etch the film of the sheet-like material by irradiating the substrate on which the film of the sheet-like material is formed with particles; and
a vacuum transfer chamber configured to transfer the substrate between the film forming device and the etching device, the vacuum transfer chamber being connected to the film forming device and the etching device.

10. The substrate processing apparatus according to claim 9, wherein
the etching device is one of a gas cluster ion beam irradiator configured to irradiate the substrate with a gas cluster ion beam, a gas cluster beam irradiator configured to irradiate the substrate with a gas cluster beam, or an ion beam irradiator configured to irradiate the substrate with an ion beam.

11. The substrate processing apparatus according to claim 9, wherein
the etching device includes a support configured to support the substrate, and
the support is configured to support the substrate at an inclination with respect to an incident direction of the particles.
